(19) United States
(12) Patent Application Publication
(10) Pub. No.: US 2008/0072732 A1
(43) Pub. Date: Mar. 27, 2008

(54) CUSHION AND CUTTING DEVICE OF MANUFACTURING THE SAME

(75) Inventors: Jun Wan, Jiangsu Province (CN); Xiang-Lin Li, Jiangsu Province (CN)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: BENQ CORPORATION, Taoyuan Shien (TW)

(21) Appl. No.: 11/836,850

(22) Filed: Aug. 10, 2007

(30) Foreign Application Priority Data
Sep. 22, 2006 (TW) 95135112

(51) Int. Cl. B26D 5/00; H05K 7/14

(52) U.S. Cl. 83/821; 361/679

(57) ABSTRACT

A cushion disposed on a display panel is provided. The display panel has an active area and an inactive area surrounding the active area. The cushion includes a body having a first surface, a second surface and a concave channel. The second surface is joined to the inactive area. The concave channel passes through the first surface and the second surface so as to expose the active area. The concave channel has an inclined lateral wall, which forms a first inclination angle and a second inclination angle with the first surface and the second surface respectively, such that the area of the first surface is larger than that of the second surface.

This application claims the benefit of Taiwan application Serial No. 95135112, filed Sep. 22, 2006, the subject matter of which is incorporated herein by reference.

### BACKGROUND OF THE INVENTION

1. Field of the Invention

The invention relates in general to a cushion and a cutting device of manufacturing the same, and more particularly to a cushion used in a small electronic device and a cutting device of manufacturing the same.

2. Description of the Related Art

Normally, a cushion is made from a porous foam material and is provided with excellent features of insulation and buffer. Therefore, the cushion is widely used in the locations of electronic devices requiring buffer or sealing. For example, when the cushion is used in a mobile phone, the cushion is disposed in the gap between the casing and the display panel of the mobile phone for reducing the impact on the display panel when the mobile phone receives a force. Besides, the cushion can also be utilized to seal the joint seam of the casing to make the internal space of the mobile phone dust-proof.

When the cushion disposes between the casing and the display panel of the mobile phone, the normal practice to maintain the visual esthetics and make the cushion invisible to the user while viewing the display panel is to draw back the cushion by a distance. Referring to FIG. 1, a perspective of a conventional cushion disposed between the casing and the display panel is shown. The cushion 10 is disposed between a casing 13 and a display panel 12, jointed to the casing 13 via an adhesive 14, and drawn back from the edge of the casing 13 by a distance d, such that the cushion 10 will not be exposed outside the casing 13 within the range of a view-angle direction S1 from the user.

However, the current design of mobile phone is directed towards lightweight and miniaturization while the visual area of the display panel is enlarged, therefore the area of the cushion and that of the casing are decreased relatively. As indicated in FIG. 1, the way of drawing back the cushion 10 by a distance d reduces the coating area of the adhesive 14 on the cushion 10, causing the cushion 10 unable to be firmly jointed to the casing 13. As a result, before a mobile phone is assembled, the cushion 10 is easily shifted or comes off, affecting the assembly quality of the mobile phone.

### SUMMARY OF THE INVENTION

The invention is directed to a cushion and a cutting device of manufacturing the same. The cushion has an inclined lateral wall and the area coated with adhesive on the cushion can be increased accordingly, such that the cushion and the casing are firmly jointed with each other.

According to one aspect of the present invention, a cushion disposed on a display panel is provided. The display panel has an active area and an inactive area surrounding the active area. The cushion includes a body having a first surface, a second surface and a concave channel. The second surface is joined to the inactive area. The concave channel passes through the first surface and the second surface so as to expose the active area. The concave channel has an inclined lateral wall, which forms a first inclination angle and a second inclination angle with the first surface and the second surface respectively, such that the area of the first surface is larger than that of the second surface.

According to another aspect of the present invention, a cutting device used for cutting a cushion is provided. The cutting device includes a pushing plate, a cutter and a base. The pushing plate has a sliding track. The cutter includes a cutter base and a cutter blade. The cutter base is movably disposed at the sliding track. The cutter blade is jointed to the cutter base and forms an inclination angle with the pushing plate. The base parallel to and disposed under the pushing plate has a sliding channel. The cutter blade is movably disposed in the sliding channel. As the cushion is parallel to and disposed under the base, the pushing plate moves along the base in a pushing plate moving direction and drives the cutter blade to move in the sliding channel along a cutter moving direction for cutting the cushion and forming a concave channel therein.

The invention will become apparent from the following detailed description of the preferred but non-limiting embodiment. The following description is made with reference to the accompanying drawings.

### BRIEF DESCRIPTION OF THE DRAWINGS

FIG. 1 (Prior Art) is a perspective of a conventional cushion disposed between the casing and the display panel;

FIG. 2A is a perspective of a cushion disposed between the casing and the display panel according to the preferred embodiment of the invention;

FIG. 2B is a 3-D perspective of the cushion of FIG. 2A;

FIG. 3A is a perspective of a cutting device for manufacturing the cushion of FIG. 2B;

FIG. 3B is a perspective of the cutting device of FIG. 3A while cutting the cushion; and

FIG. 4 is a perspective of the cushion of FIG. 1 and the cushion of FIG. 2A.

### DETAILED DESCRIPTION OF THE INVENTION

Referring to both FIGS. 2A and 2B. FIG. 2A is a perspective of a cushion disposed between the casing and the display panel according to the preferred embodiment of the invention. FIG. 2B is a 3-D perspective of the cushion of FIG. 2A. The cushion 20 is disposed on a display panel 22. The display panel has an active area 22a and an inactive area 22b surrounding the active area 22a. As indicated in FIG. 2B, the cushion 20 includes a body 21 having a first surface 21a, a second surface 21b and a concave channel 21c. The second surface 21b is joined to the inactive area 22b. The concave channel 21c passes through the first surface 21a and the second surface 21b so as to expose the active area 22a. The concave channel 21c has an inclined lateral wall 21d, which forms a first inclination angle θ1 and a second inclination angle θ2 with the first surface 21a and the second surface 21b respectively, such that the area of the first surface 21a is larger than that of the second surface 21b.

Furthermore, the first surface 21a of the cushion 20 is jointed to the casing 23 via an adhesive 24. As indicated in FIG. 2A, the first inclination angle θ1 is an acute angle, and the second inclination angle θ2 is an obtuse angle, such that the area of the first surface 21a is larger than that of the second surface 21b. As a result, the contact area between the cushion 20 and the casing 23 is increased and a larger area can be coated with the adhesive 24 such that the cushion 20 can be firmly jointed to the casing 23. Besides, the inclined lateral wall 21d is approximately parallel to a view-angle direction S2, such that the cushion 20 will not be exposed outside the casing 23 within the range of the view-angle direction S2.

Moreover, the cushion 20 of FIG. 2B is frame-shaped and is correspondingly jointed to the inactive area 22b, such that the peripheral of the display panel 22 is protected by the cushion. The concave channel 21c is substantially located at the center of the body 21, and the size of the concave channel 21c is substantially equal to that of the active area 22a, such that the active area 22a is completely exposed through the concave channel 21c for providing the display panel 22 with a maximum visible area.

In addition, the cushion 20 is made from microcellular polymer, which provides elasticity for the cushion 20 to be jointed to the casing 23 and the display panel 22 seamlessly. Therefore, the space between the casing 23 and the display panel 22 can be dust-proof.

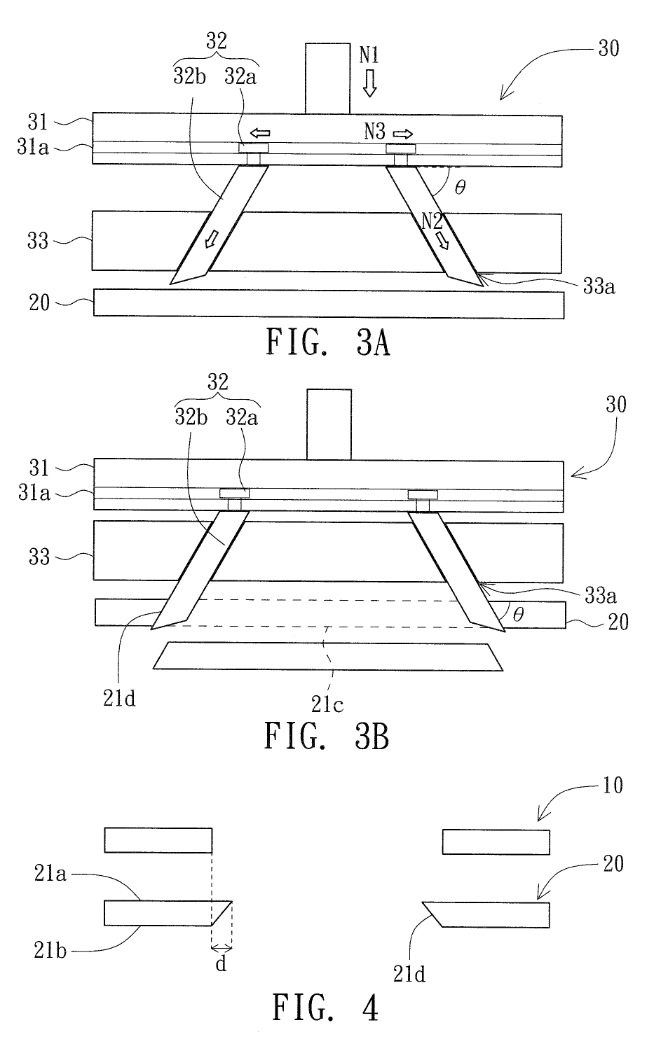

Referring to both FIG. 2B and FIG. 3A. FIG. 3A is a perspective of a cutting device for manufacturing the cushion of FIG. 2B. The cutting device 30 is used for cutting the cushion 20. The cutting device 30 includes a pushing plate 31, a cutter 32 and a base 33. The pushing plate 31 has a sliding track 31a. The cutter 32 includes a cutter base 32a movably disposed at the sliding track 31a and a cutter blade 32b joining to the cutter base 32a. The cutter blade 32b forms an inclination angle θ with the pushing plate 31. The inclination angle θ is equivalent to the first inclination angle θ1 between the inclined lateral wall 21d and the first surface 21a as indicated in FIG. 2B. The base 33 parallel to and disposed under the pushing plate 31 has a sliding channel 33a. The cutter blade 32b is movably disposed in the sliding channel 33a. The cushion 20 is parallel to and disposed under the base 33. Referring to FIG. 3B, a perspective of the cutting device of FIG. 3A while cutting the cushion is shown. As the pushing plate 31 moves with respect to the base 33 along a pushing plate moving direction N1, the pushing plate 31 drives the cutter blade 32b to move along the sliding channel 33a in a cutter moving direction N2 for cutting the cushion 20 and forming a concave channel 21c therein. The inclined wall 21d of the concave channel 21c forms the inclination angle θ with the base 33.

As the pushing plate 31 moves with respect to the base 33 along the pushing plate moving direction N1, the cutter base 32a moves along the sliding track 31a in a cutter base sliding direction N3. The cutter base sliding direction N3 is perpendicular to the pushing plate moving direction N1. The shape of the sliding track 31a is T-shaped for example, and the shape of the cutter base 32a is an indentation corresponding to the T-shape, such that the cutter base 32a goes with the sliding track 31a and the cutter base 32a is able to move along the sliding track 31a. The pushing plate 31 is made from a rigid material such that the pushing plate 31 will not be deformed when the cutting device 30 cuts the cushion 20 and that the cutting angle on the cushion 20 by the cutter blade 32b is fixed.

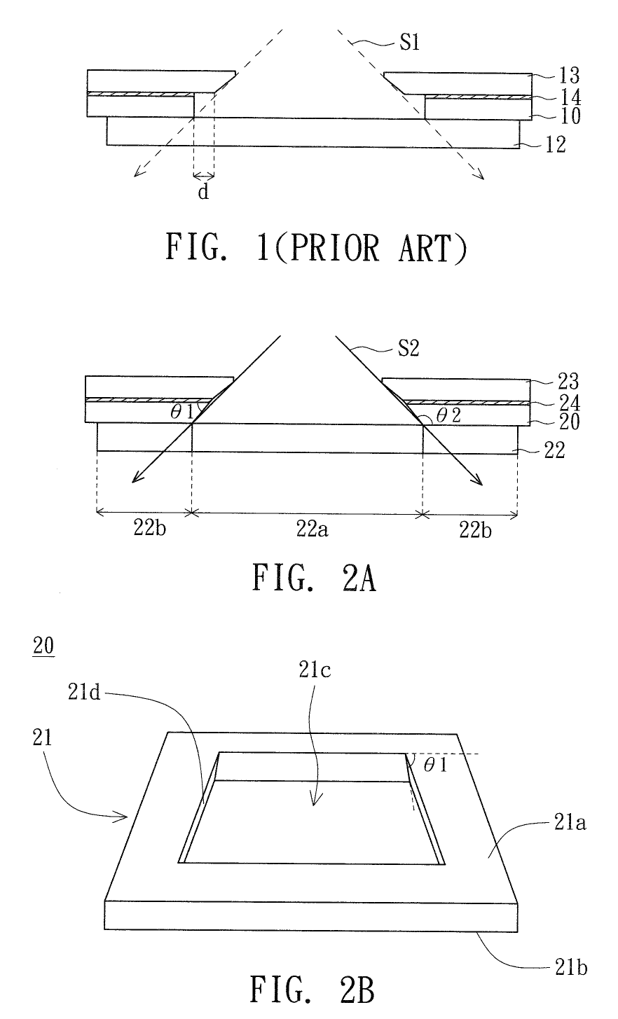

Referring to FIG. 4, a perspective of the cushion of FIG. 1 and the cushion of FIG. 2A is shown. Compared with the conventional cushion 10, the cushion 20 of the preferred embodiment of the invention has an inclined lateral wall 21d, such that the first surface 21a of the cushion 20 of the invention is larger than the conventional cushion 10 by a drawn back distance d. Therefore, the cushion 20 of the invention has a larger first surface 21a and more area can be coated with the adhesive. Besides, the way of forming an inclined lateral wall 21d on the cushion 20 does not increase the area of the second surface 21b. That is, the user will not see the cushion 20 when viewing the display panel. To summarize, the cushion 20 of the invention is jointed to the casing more tightly, and the cushion 20 will not be exposed outside the casing 23 within the range of the view-angle direction S2 (illustrated in FIG. 2A).

According to the cushion and the cutting device of manufacturing the same disclosed in the above preferred embodiment of the invention, the cutting device cuts the cushion and forms a concave channel therein. The concave channel has an inclined lateral wall, which forms a first inclination angle and a second inclination angle with the first surface and the second surface of the cushion respectively. The first inclination angle is an acute angle, and the second inclination angle is an obtuse angle. Thus, the area of the first surface of the cushion is larger than that of the second surface. The advantage for the above design is that with a larger first surface, the cushion is jointed to the casing more firmly, such that the cushion will not be shifted or come off while assembling the casing with the display panel. The above design assures that the cushion precisely corresponds to the inactive area of the display panel and that the concave channel corresponds to the active area of the display panel, such that the peripheral of the display panel is protected by the cushion and the active area is completely exposed through the concave channel for providing the display panel with a maximum visible area.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A cushion disposed on a display panel, wherein the display panel has an active area and an inactive area surrounding the active area, the cushion comprises:
a body having a first surface, a second surface and a concave channel, wherein the second surface is joined to the inactive area, and the concave channel passes through the first surface and the second surface so as to expose the active area;
wherein, the concave channel has an inclined lateral wall which forms a first inclination angle and a second inclination angle with the first surface and the second surface respectively such that the area of the first surface is larger than that of the second surface.

2. The cushion according to claim 1, wherein the cushion is frame-shaped.

3. The cushion according to claim 1, wherein the concave channel is substantially located at the center of the body.

4. The cushion according to claim 1, wherein the first surface is joined to a casing, such that the cushion is disposed between the casing and the display panel for protecting the display panel.

5. The cushion according to claim 4, wherein the first surface is jointed to the casing via an adhesive.

6. The cushion according to claim 1, wherein the first inclination angle is an acute angle.

7. The cushion according to claim 1, wherein the second inclination angle is an obtuse angle.

8. The cushion according to claim 1, wherein the cushion is made from microcellular polymer.

9. A cutting device for cutting a cushion comprising:
a pushing plate having a sliding track;
a cutter, comprising:
a cutter base movably disposed at the sliding track; and
a cutter blade jointed to the cutter base and forming an inclination angle with the pushing plate; and
a base paralelly disposed under the pushing plate, wherein the base has a sliding channel, and the cutter blade is movably disposed in the sliding channel;
wherein, as the cushion is parallel to and disposed under the base, the pushing plate moves with respect to the base along a pushing plate moving direction and drives the cutter blade to move in the sliding channel along a cutter moving direction for cutting the cushion and forming a concave channel therein.

10. The cutting device according to claim 9, wherein the inclination angle is formed between an inclined lateral wall of the concave channel and the base.

11. The cutting device according to claim 9, wherein the cutter base moves along the sliding track in a cutter base sliding direction, and the cutter base sliding direction is perpendicular to the pushing plate moving direction.

12. The cutting device according to claim 9, wherein the cross-section of the sliding track is T-shaped.

13. The cutting device according to claim 9, wherein the inclination angle is an acute angle.

14. The cutting device according to claim 9, wherein the pushing plate is made from a rigid material.
